(19) United States
(12) Patent Application Publication
(10) Pub. No.: US 2019/0006576 A1
(43) Pub. Date: Jan. 3, 2019

(54) SURFACE-MOUNT PIEZOELECTRIC SENSOR APPLIED TO LOGISTICS FOR REAL-TIME MONITORING

(71) Applicant: SOUTHERN TAIWAN UNIVERSITY OF SCIENCE AND TECHNOLOGY, TAINAN CITY (TW)

(72) Inventors: CHENG HSIN CHUANG, TAINAN CITY (TW); CHUNG LIN HUANG, TAINAN CITY (TW); CHENG AN WANG, TAINAN CITY (TW)

(21) Appl. No.: 15/637,222

(22) Filed: Jun. 29, 2017

(51) Int. Cl. H01L 41/113; H01L 41/053

(52) U.S. Cl. CPC H01L 41/1132; H01L 41/053

(57) ABSTRACT

A surface-mount piezoelectric sensor applied to logistics for real-time monitoring is provided. The piezoelectric sensor includes a flexible substrate in the form of a cross and a conductive line formed on the flexible substrate. A plurality of sensing members corresponding in number to end faces of a packaging box is adhered to the conductive line. The cross-shaped piezoelectric sensor is placed at the bottom of the packaging box, and the sensing members of the piezoelectric sensors are bonded to the respective end faces of the packaging box by means of a turnover operation, thereby simplifying the operation process and providing an all-round monitoring effect.

### FIELD OF THE INVENTION

The present invention relates to a piezoelectric sensor, and more particularly to a piezoelectric sensor which can be quickly attached to each end face of a packaging box containing goods to detect whether the goods are thrown or pressed heavily or unsealed during transportation.

### BACKGROUND OF THE INVENTION

Taiwan Patent No. I289795 discloses a radio frequency tag provided with an electronic seal to prevent goods from being exchanged or lost and a tracking system by using the radio frequency tag to identify the condition of the electronic seal. However, the electronic seal is unable to know the condition of the goods or to clarify the attribution of responsibility when the goods are damaged. Taiwan Utility Model No. M483492 discloses an impact indicator and a logistics monitoring and management system having the impact indicator. When the goods coupled with the impact indicator are impacted or shaken, the impact indicator will present a permanent color change. However, the system needs to take pictures and upload information, which consumes time and manpower. Taiwan Patent No. I484440 discloses a method and a system for logistics delivery and identification to prevent an imposter from getting the goods or to prevent logistics personnel from privately taking possession of the goods. However, this system is unable to know the condition of the goods or to clarify the attribution of responsibility when the goods are damaged.

In order to solve the shortcomings of the prior art, the inventor of the present invention filed an application in 2015 and attained Taiwan Patent No. I557680 tilted “logistics monitoring system by using piezoelectric sensing label”. A piezoelectric sensing label is affixed to the top or bottom of the goods, so that the piezoelectric sensing label on the goods can be scanned at the logistics station by using a scanner for recording the goods. During the carrying or transportation of the goods, the piezoelectric value detected by the piezoelectric sensing label is transmitted to a vehicle, and then the vehicle transmits a signal to a cloud management system for monitoring the goods instantaneously. This way can clarify the attribution of responsibility when the goods are damaged. However, the piezoelectric sensing label is affixed to the sealed portion of the packaging box containing the goods, that is, the top or the bottom of the packaging box containing the goods. If the other end faces of the packaging box are damaged, it may have a flaw in monitoring. Although the piezoelectric sensing labels can be affixed to the six end faces of the packaging box to achieve an all-round monitoring, it is required to affix the piezoelectric sensing labels one by one to the respective end faces of the packaging box. When the piezoelectric sensing label is affixed to the bottom of the packaging box, it may cause great inconvenience of operation because the goods are too heavy and the packaging box cannot be overturned. Accordingly, the inventor of the present invention has devoted himself based on his many years of practical experiences to solve these problems.

### SUMMARY OF THE INVENTION

In view of the shortcomings of the conventional piezoelectric sensing label invented by the inventor of the present invention, the primary object of the present invention is to provide a piezoelectric sensor in the form of a stripe or cross. The piezoelectric sensor can be quickly coupled to each end face of a packaging box by means of a turnover operation.

According to one aspect of the present invention, a surface-mount piezoelectric sensor applied to logistics for real-time monitoring is provided. The piezoelectric sensor comprises a flexible substrate in the form of a stripe and a conductive line formed on the flexible substrate. A plurality of sensing members is adhered to the conductive line. A rear end of the conductive line is provided with a connecting member for connecting the piezoelectric sensor with a back-end circuit.

According to another aspect of the present invention, a surface-mount piezoelectric sensor applied to logistics for real-time monitoring is provided. The piezoelectric sensor comprises a flexible substrate in the form of a cross and a conductive line formed on the flexible substrate. A plurality of sensing members corresponding in number to end faces of a packaging box is adhered to the conductive line. A rear end of the conductive line is provided with a connecting member for connecting the piezoelectric sensor with a back-end circuit.

Based on the aforesaid, a plurality of piezoelectric sensors in the form of a stripe is affixed to a packaging box containing goods in a crisscross pattern so that the sensing members of the piezoelectric sensors can be bonded to the respective end faces of the packaging box. Alternatively, the cross-shaped piezoelectric sensor is placed at the bottom of the packaging box containing goods, and the sensing members of the piezoelectric sensor are bonded to the respective end faces of the packaging box by means of a turnover operation, thereby simplifying the operation process and providing an all-round monitoring effect.

### BRIEF DESCRIPTION OF THE DRAWINGS

FIG. 1 is an exploded view in accordance with a first embodiment of the present invention;

FIG. 2 is a perspective view in accordance with the first embodiment of the present invention;

FIG. 3 is a schematic view in accordance with the first embodiment of the present invention when in use;

FIG. 4 and FIG. 5 are further schematic views in accordance with the first embodiment of the present invention when in use;

FIG. 6 is a perspective view in accordance with a second embodiment of the present invention;

FIG. 7 is a schematic view in accordance with the second embodiment of the present invention when in use; and

FIG. 8 is a schematic view showing the real-time monitoring of the present invention.

### DETAILED DESCRIPTION OF THE PREFERRED EMBODIMENTS

Embodiments of the present invention will now be described, by way of example only, with reference to the accompanying drawings.

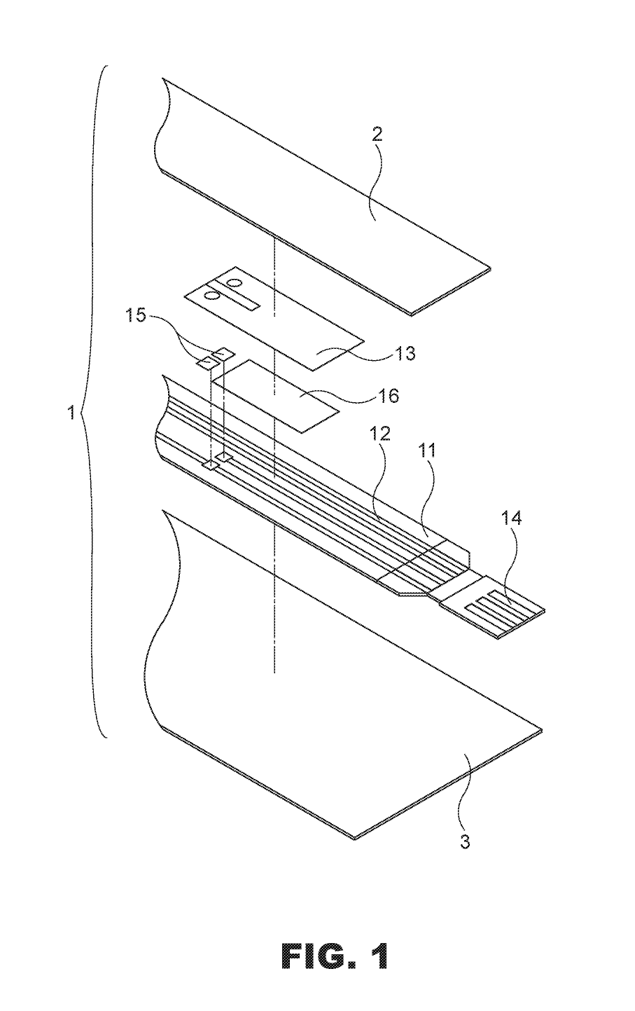

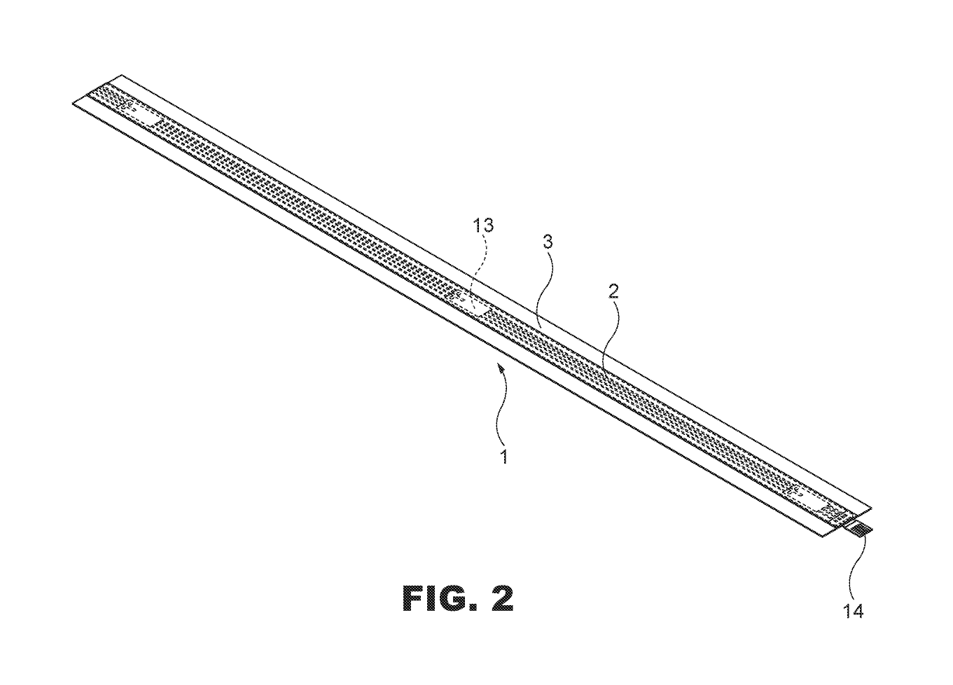

First, referring to FIG. 1 and FIG. 2, a piezoelectric sensor 1 in accordance with a first embodiment of the present invention is in the form of a stripe, and comprises a flexible substrate 11 and a conductive line 12 formed on the flexible substrate 11. Preferably, the flexible substrate 11 is a flexible printed circuit board. The positive and negative electrodes of three sensing members 13 are adhered to the conductive line 12 through an anisotropic conductive film 15. The sensing members 13 are attached to the flexible substrate 11 with an optical adhesive 16. A connecting member 14 is provided at a rear end of the conductive line 12 for connecting the piezoelectric sensor 1 with a back-end circuit. Preferably, the connecting member 14 is a connecting finger.

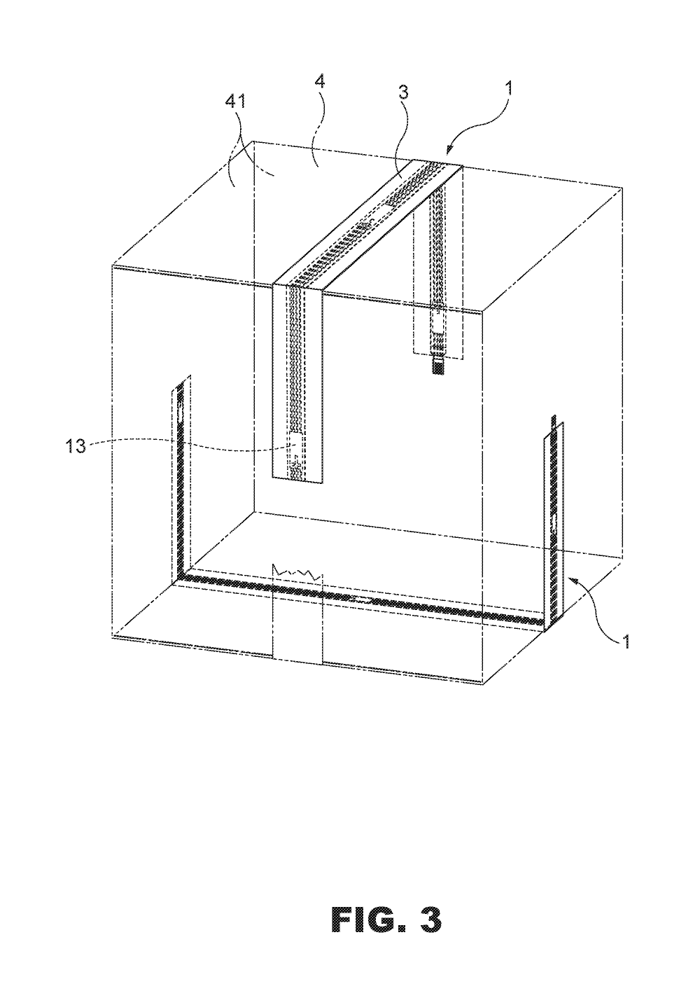

Referring to FIG. 2 and FIG. 3, the piezoelectric sensor 1 can be attached to an adhesive surface of a transparent tape 3 with a double-sided adhesive tape 2. After a packaging box 4 containing goods is sealed, the bottom of the packaging box 4 is placed over one piezoelectric sensor 1, and the three sensing members 13 of the piezoelectric sensor 1 are attached to three end faces 41 of the packaging box 4 by means of the transparent tape 3. Another piezoelectric sensor 1 is placed over the packaging box 4, and the three sensing members 13 of this piezoelectric sensor 1 are attached to the other three end faces 41 of the packaging box 4 by means of the transparent tape 3. The six sensing members 13 are attached to the six end faces 41 of the packaging box 4 by means of two affixing steps in a crisscross pattern, thereby completely monitoring the condition of the goods.

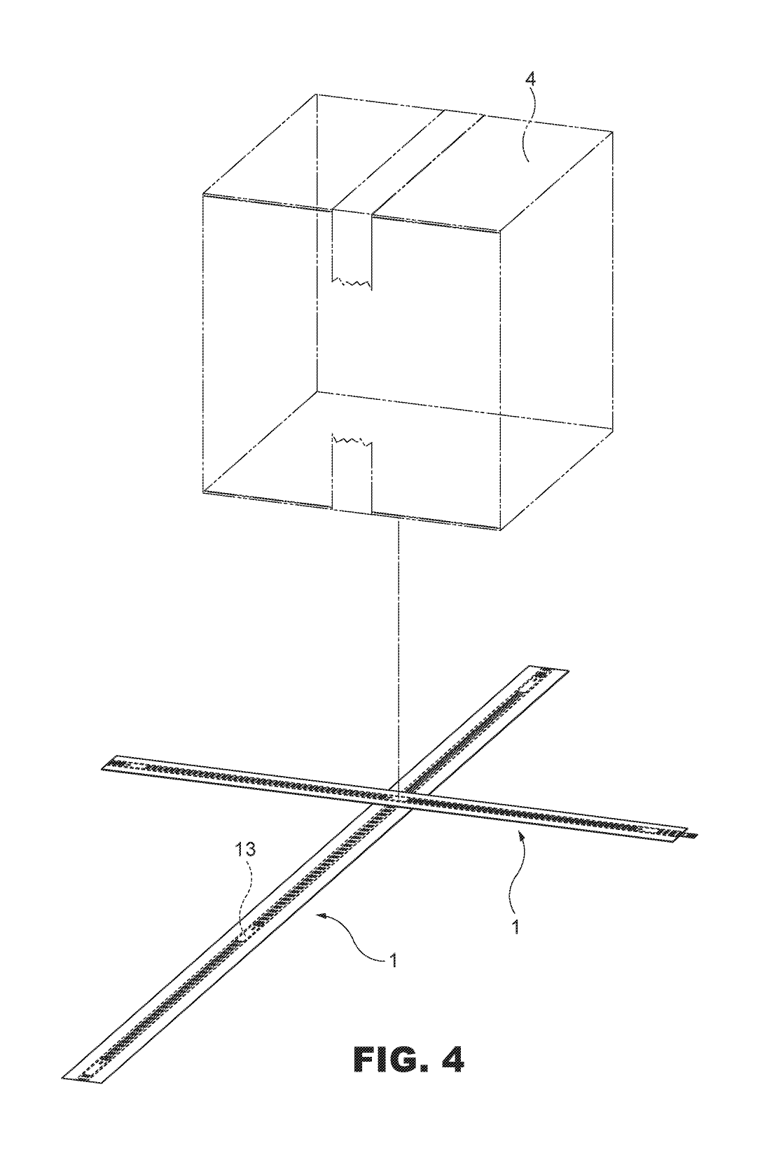

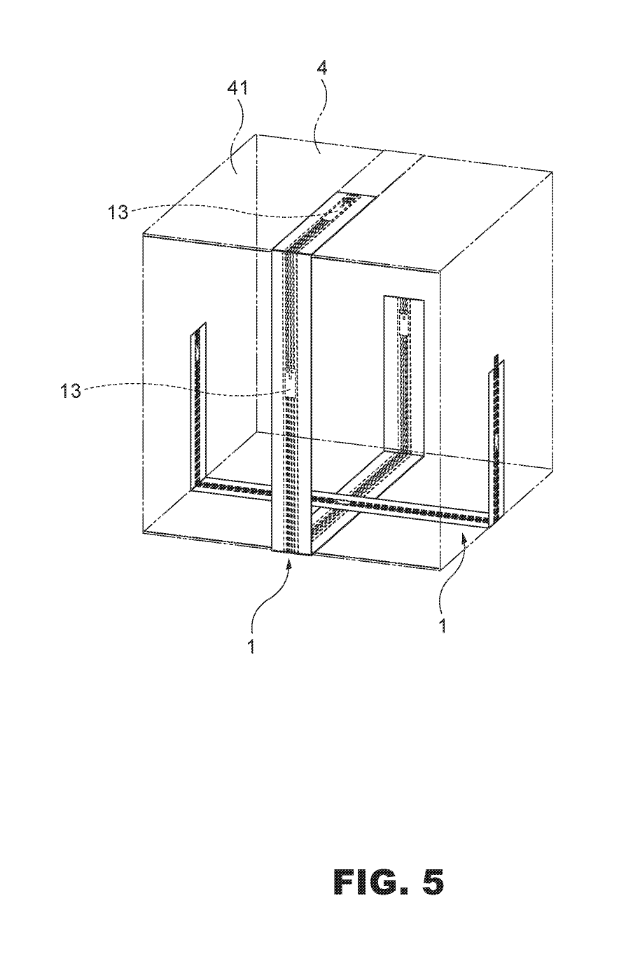

Next, referring to FIG. 4, the length of the piezoelectric sensor 1 and the setting position of the sensing members 13 can be changed according to the needs. The two piezoelectric sensors 1 are arranged in a cross shape by overlapping. The packaging box 4 containing the goods can be placed over the overlapped portion of the two piezoelectric sensors 1, and the piezoelectric sensors 1 are affixed to the packaging box 4 (as shown in FIG. 5) by means of a turnover operation, while the six sensing members 13 are located on the six end faces 41 of the packaging box 4, respectively.

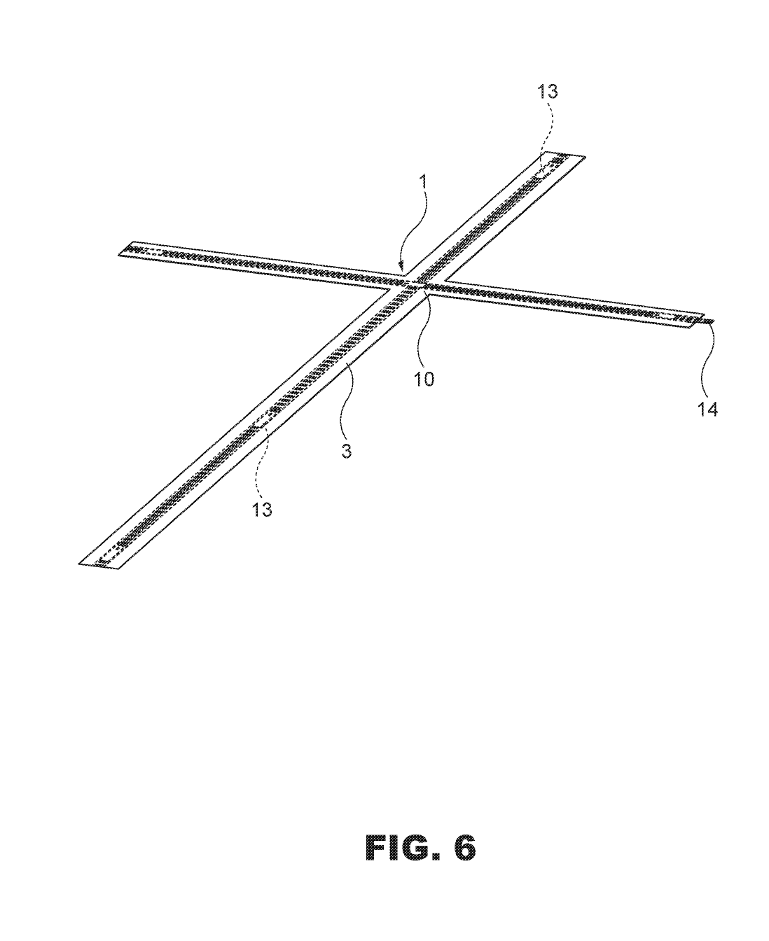

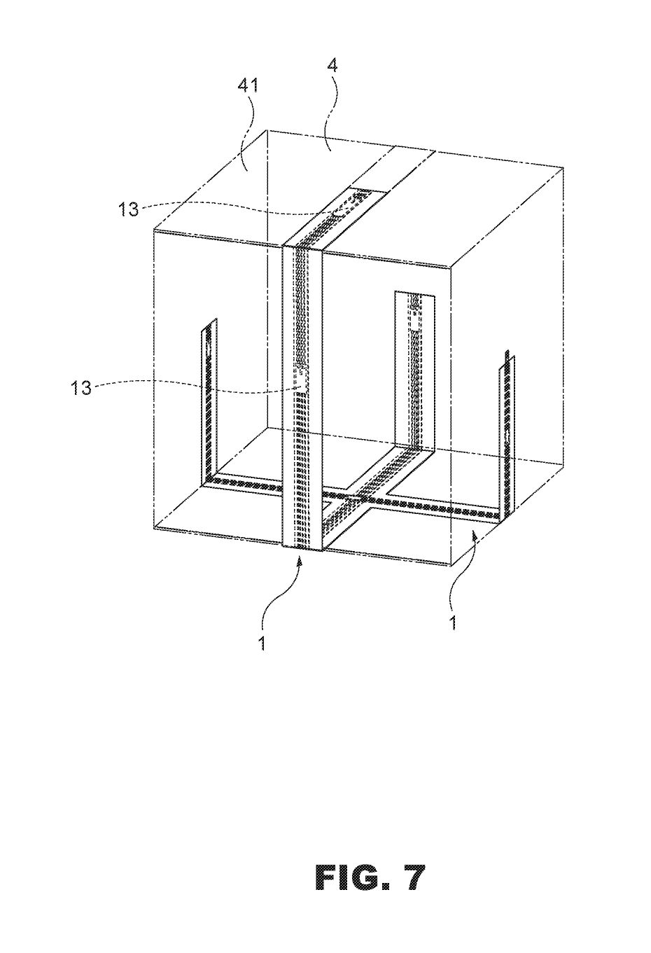

Referring to FIG. 6, a piezoelectric sensor 1 in accordance with a second embodiment of the present invention is in a cross shape having an intersection 10, and comprises a flexible substrate 11 and a conductive line 12 formed on the flexible substrate 11 (referring to FIG. 1). Preferably, the flexible substrate 11 is a flexible printed circuit board. The positive and negative electrodes of sensing members 13 corresponding in number to end faces 41 of a packaging box 4 are adhered to the conductive line 12 through an anisotropic conductive film 15. The sensing members 13 are attached to the flexible substrate 11 with an optical adhesive 16. A connecting member 14 is provided at a rear end of the conductive line 12 for connecting the piezoelectric sensor 1 with a back-end circuit. Preferably, the connecting member 14 is a connecting finger. The piezoelectric sensor 1 can be attached to an adhesive surface of a transparent tape 3 with a double-sided adhesive tape 2. After a packaging box 4 containing goods is sealed, the bottom of the packaging box 4 is placed over the intersection 10 of the piezoelectric sensor 1, and the piezoelectric sensor 1 is affixed to the packaging box 4 (as shown in FIG. 7) by means of a turnover operation, while the sensing members 13 are located on the end faces 41 of the packaging box 4, respectively.

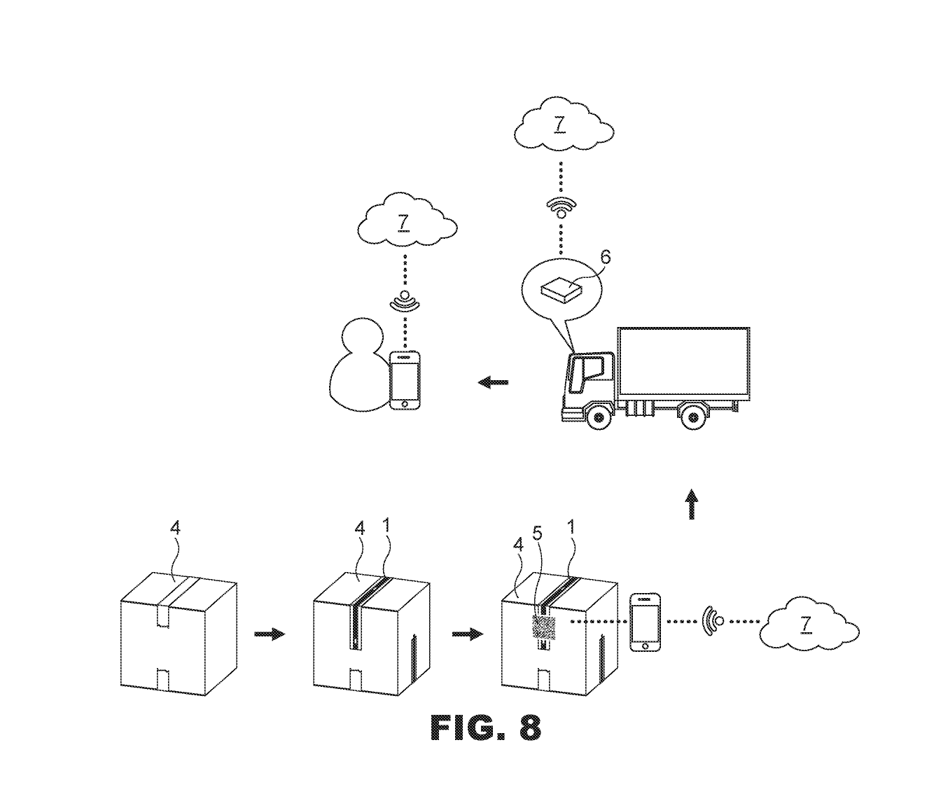

The piezoelectric sensor 1 can cooperate with a monitoring system to achieve an all-round monitoring. Please refer to FIG. 8, the piezoelectric sensor 1 is coupled with a smart circuit of an analog-to-digital converter and a microcontroller unit, and is connected with a QRCode 5, and is placed in a vehicle 6 for transporting the goods, and is communicated with a cloud management system 7 via the Internet. After the logistics industry affixes the piezoelectric sensor 1 to the outside of the packaging box 4, the packaging box 4 is stored at the logistics station and waits to be transported. Before shipment, the QRCode 5 on the outside of the packaging box 4 is scanned and then recoded in the cloud management system 7, while the smart circuit drives the power supply of the piezoelectric sensor 1 for sensing and monitoring. During the carrying and transportation of the goods, the sensing members 13 affixed to the six end faces 41 of the packaging box 4 generate monitoring signals (referring to FIG. 2) to be transmitted to the cloud management system 7 through the vehicle 6, so that the recipient and the sender can keep abreast of the condition of the goods and the goods can be delivered to the recipient safely. This way can prevent the goods from being broken and damaged because of being thrown or pressed heavily or being unsealed. When the goods are damaged, the information received by the cloud management system 7 and the time of receipt help the user understand when the goods are damaged in order to clarify the attribution of responsibility.

Thereby, the piezoelectric sensor of the present invention can achieve the following effects:

1. The piezoelectric sensor of the present invention may be in the form of a long stripe, so the length of the piezoelectric sensor and the setting position of the sensing members can be changed according to the needs. Two piezoelectric sensors in the form of a stripe are arranged in a cross shape by overlapping and attached to the packaging box, while the sensing members are affixed to the six end faces of the packaging box respectively, thereby simplifying the operation process and the operation time of the logistics staff

2. The piezoelectric sensor of the present invention may be in a cross shape. After the packaging box is placed on the intersection of the cross-shaped piezoelectric sensor, the piezoelectric sensor is attached to the packaging box by means of a turnover operation, while the sensing members are affixed to the respective end faces of the packaging box, thereby simplifying the operation process and the operation time of the logistics staff.

3. The sensing members of the piezoelectric sensor of the present invention can be attached to the six end faces of the packaging box containing the goods by means of affixing, thereby realizing an all-round monitoring effect. The present invention can be widely applied to high-priced products, technology products, military confidential products or fragile products, reducing the probability that the goods are exchanged, damaged or destroyed.

4. The piezoelectric sensor of the present invention can control a plurality of sensing members through the connecting finger, thereby saving the process and time of packaging the piezoelectric sensor.

5. The piezoelectric sensor of the invention can cooperate with the vehicle and the cloud management system to achieve an all-round monitoring. When the goods are damaged, the information received by the cloud management system and the time of receipt help the user understand when the goods are damaged in order to clarify the attribution of responsibility, thereby, enhancing the safety of goods and improving the tripartite mutual trust mechanism of the sender, the recipient and the logistics industry.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A surface-mount piezoelectric sensor applied to logistics for real-time monitoring, comprising a flexible substrate in the form of a stripe and a conductive line formed on the flexible substrate, a plurality of sensing members being adhered to the conductive line, a rear end of the conductive line being provided with a connecting member for connecting the piezoelectric sensor with a back-end circuit.

2. The surface-mount piezoelectric sensor applied to logistics for real-time monitoring as claimed in claim 1, wherein the flexible substrate is a flexible printed circuit board.

3. The surface-mount piezoelectric sensor applied to logistics for real-time monitoring as claimed in claim 1, wherein the connecting member is a connecting finger.

4. The surface-mount piezoelectric sensor applied to logistics for real-time monitoring as claimed in claim 1, wherein the piezoelectric sensor is attached to an adhesive surface of a transparent tape with a double-sided adhesive tape.

5. A surface-mount piezoelectric sensor applied to logistics for real-time monitoring, comprising a flexible substrate in the form of a cross and a conductive line formed on the flexible substrate, a plurality of sensing members corresponding in number to end faces of a packaging box being adhered to the conductive line, a rear end of the conductive line being provided with a connecting member for connecting the piezoelectric sensor with a back-end circuit.

6. The surface-mount piezoelectric sensor applied to logistics for real-time monitoring as claimed in claim 5, wherein the flexible substrate is a flexible printed circuit board.

7. The surface-mount piezoelectric sensor applied to logistics for real-time monitoring as claimed in claim 5, wherein the connecting member is a connecting finger.

8. The surface-mount piezoelectric sensor applied to logistics for real-time monitoring as claimed in claim 5, wherein the piezoelectric sensor is attached to an adhesive surface of a transparent tape with a double-sided adhesive tape.
